(19) United States
(12) Patent Application Publication
(10) Pub. No.: US 2025/0370065 A1
(43) Pub. Date: Dec. 4, 2025

(54) GROUND FAULT DETECTION TECHNIQUES IN MOBILE MACHINES

(71) Applicant: Caterpillar Inc., Peoria, IL (US)

(72) Inventors: Matthew Lawrence Hendrickson, Dunlap, IL (US); Bradley Scott Bailey, Edwards, IL (US); Jason Lee Miller, Princeville, IL (US)

(73) Assignee: Caterpillar Inc., Peoria, IL (US)

(21) Appl. No.: 18/680,695

(22) Filed: May 31, 2024

(51) Int. Cl. G01R 31/52; G01R 19/00; G01R 31/00

(52) U.S. Cl. CPC G01R 31/52; G01R 19/0084; G01R 31/006

(57) ABSTRACT

Techniques are described for detecting and isolating ground faults within power converter systems, particularly in high-voltage and high-power applications such as mobile machines. The disclosed techniques monitor an electrical parameter of the system to enable the rapid identification and precise localization of ground faults.

### FIELD OF THE DISCLOSURE

This document pertains generally, but not by way of limitation, to techniques for detecting ground faults.

### BACKGROUND

Electric or hybrid machines are widely used as alternatives to their mechanical counterparts in industrial applications due to their higher efficiency and lower maintenance requirements. A high-voltage power system is required for driving an electric machine that incorporates a high-voltage (HV) electrical drive motor and electric auxiliaries. High voltage, which may also be referred to as hazardous voltage, is a practical voltage potential used for electric drive machines. This generally includes AC and DC voltages greater than 50 volts. The integrity of the high-voltage power system is important to the reliability of the machine. Typically, the machine frame will be electrically isolated from the terminals or conductors of the high-voltage electrical components in the high-voltage power system.

Under normal conditions, leakage currents on the order of microamps exist between the conductors of the high-voltage electrical components and the machine frame, and accordingly, the leakage resistances between the conductors of the high-voltage electrical components and the frame are normally very high. Under such conditions, no ground fault exists in the high-voltage power system. However, electric current from a high-voltage electrical component may leak into a machine frame and cause a ground fault. Such leakage currents, when significant, may be an indication of machine component fatigue or failure of a conductor's insulation. In order to ensure the proper operating conditions of the machine, it is desirable to detect ground faults such as an electrical leakage between the conductors of the high voltage electrical components and the machine frame.

WO2011153581A1 is directed to a method of digital sampling of a current or group of currents in an electrical system including using in said sampling, sufficient bandwidth to reconstruct the amplitude and phase of a synthesized power frequency and its harmonics and a fundamental carrier frequency of switching electronics and modulation sidebands.

### SUMMARY OF THE DISCLOSURE

This disclosure is directed to techniques for detecting and isolating ground faults within power converter systems, particularly in high-voltage and high-power applications such as mobile machines. The disclosed techniques monitor an electrical parameter of the system to enable the rapid identification and precise localization of ground faults. In some aspects, this disclosure is directed to a mobile machine configured for detecting a source of a ground fault, the mobile machine comprising: a battery string including at least one battery cell; an electrical bus coupled with the battery string; a first electrical converter and a second electrical converter, each of the first electrical converter and the second electrical converter coupled with the electrical bus, the first electrical converter configured for operating at a first switching frequency and the second electrical converter configured for operating at a second switching frequency, wherein the first switching frequency is different from the second switching frequency; a sensor coupled with the electrical bus and configured for sensing a electrical parameter of the electrical bus; and a controller configured to receive the sensed electrical parameter, the controller configured to detect ground faults by: detecting, using the sensed electrical parameter, at least one of the first switching frequency and the second switching frequency; and identifying, based on the detected at least one of the first switching frequency and the second switching frequency, at least one of the first electrical converter and the second electrical converter as the source of the ground fault.

In some aspects, this disclosure is directed to a method for detecting a source of a ground fault in a mobile machine, the method comprising: operating a first electrical converter at a first switching frequency; operating a second electrical converter at a second switching frequency, wherein the first switching frequency is different from the second switching frequency; sensing an electrical parameter of an electrical bus; receiving the sensed electrical parameter; detecting, using the sensed electrical parameter, at least one of the first switching frequency and the second switching frequency; and identifying, based on the detected at least one of the first switching frequency and the second switching frequency, at least one of the first electrical converter and the second electrical converter as the source of the ground fault.

In some aspects, this disclosure is directed to a mobile machine configured for detecting a source of a ground fault, the mobile machine comprising: a battery string including at least one battery cell; an electrical bus coupled with the battery string; a first electrical converter and a second electrical converter, each of the first electrical converter and the second electrical converter coupled with the electrical bus, the first electrical converter configured for operating at a first switching frequency and the second electrical converter configured for operating at a second switching frequency, wherein the first switching frequency is different from the second switching frequency; a voltage sensor coupled with the electrical bus and configured for sensing a voltage of the electrical bus; a controller configured to receive the voltage, the controller configured to detect ground faults by: detecting, using the voltage, at least one of the first switching frequency and the second switching frequency; and identifying, based on the detected at least one of the first switching frequency and the second switching frequency, at least one of the first electrical converter and the second electrical converter as the source of the ground fault; and a user interface configured to receive data from the controller representing the identified at least one of the first electrical converter and the second electrical converter as the source of the ground fault.

### BRIEF DESCRIPTION OF THE DRAWINGS

In the drawings, which are not necessarily drawn to scale, like numerals may describe similar components in different views. Similar components in different views may be described by like numerals. The drawings illustrate generally, by way of example, but not by way of limitation, various embodiments discussed in the present document.

FIG. 1 is a perspective view of an example of a mobile electric machine that can implement various techniques of this disclosure.

FIG. 2 is a simplified block diagram of an example of an electrical system that may implement various techniques of this disclosure.

FIG. 3 is a flow diagram of an example of AC ground fault detection using the techniques of this disclosure.

FIG. 4 is a flow diagram of another example of AC ground fault detection using the techniques of this disclosure.

FIG. 5 is a flow diagram of an example of a method for detecting a source of a ground fault in a mobile machine.

### DETAILED DESCRIPTION

Ground faults present an operational concern in electrical systems, particularly those involving power converters. A ground fault occurs when an unintended path between a live conductor and ground is established, allowing current to flow directly to the earth or grounding system. This may result from insulation failure, conductor damage, or a breach in the electrical containment. The consequences of such faults may range from equipment malfunction to and system-wide failures.

Power converters, which include devices such as rectifiers, inverters, and DC-to-DC converters, are integral components in a wide array of applications, including industrial machinery and mobile machines, such as those in industries such as mining, construction, and heavy hauling. These converters are responsible for transforming electrical power from one form to another to meet the specific needs of these applications. However, the complexity and high-power nature of modern power converters make them susceptible to ground faults, which can compromise their performance.

The detection and mitigation of ground faults in systems with power converters are challenging due to the dynamic nature of the power conversion process. In addition, the ability to precisely locate a ground fault within a complex network of interconnected components and converters is important for timely maintenance and repair. The present inventors have recognized that traditional ground fault detection methods may not be sufficiently responsive or accurate in the high-frequency, variable-load environments typical of these systems. The present inventors have recognized a need for improved techniques for the detection and isolation of ground faults in power converter systems that adequately address the challenges associated with rapid identification, precise localization, and effective mitigation of ground faults, particularly in complex and high-power applications such as mobile machines, e.g., mobile electric machines.

This disclosure is directed to techniques for detecting and isolating ground faults within power converter systems, particularly in high-voltage and high-power applications such as mobile machines. The disclosed techniques monitor an electrical parameter of the system to enable the rapid identification and precise localization of ground faults.

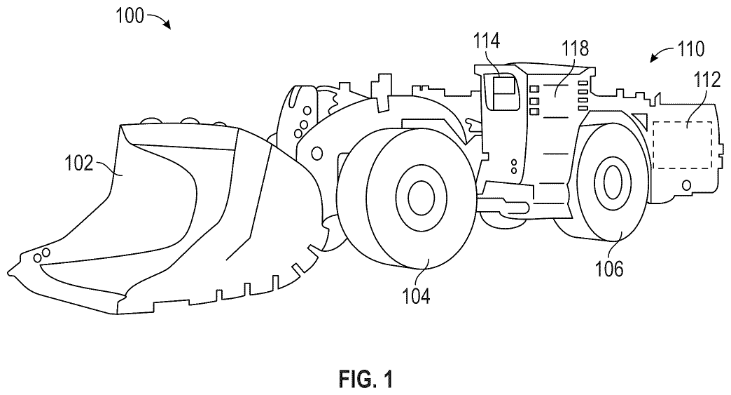

FIG. 1 is a perspective view of an example of a mobile electric machine 100 (at least partially battery powered) that can implement various techniques of this disclosure. FIG. 1 depicts a non-limiting view of an electric machine 100 in the form of a load-haul-dump (LHD) vehicle, such as for mining, including a dump bucket 102, wheels 104, 106, an operator control cabin 108, and a vehicle body 110. The wheels 104, 106 are examples of traction components. In other examples, the electric machine 100 can include traction components such as one or more tracks, in addition to or instead of the wheels.

The electric machine 100, such as an electric mine truck, an electric load haul dump truck, etc., also includes an electrical system 112. The electrical system 112 can include a DC power source, including but not limited to one or more battery strings, which can supply power to, among other things, an electric motor. The electric motor can supply rotational power to one or more systems, such as a system configured to operate various hydraulics of the dump bucket 102. The electrical system 112 can supply power to at least one traction component, such as the wheel 104, 106, and to at least one accessory component 114, such a pump motor, fan, and the like. In some examples, the electric machine 100 can include electric vehicles, such as cars, trucks, motorcycles, buses, and the like.

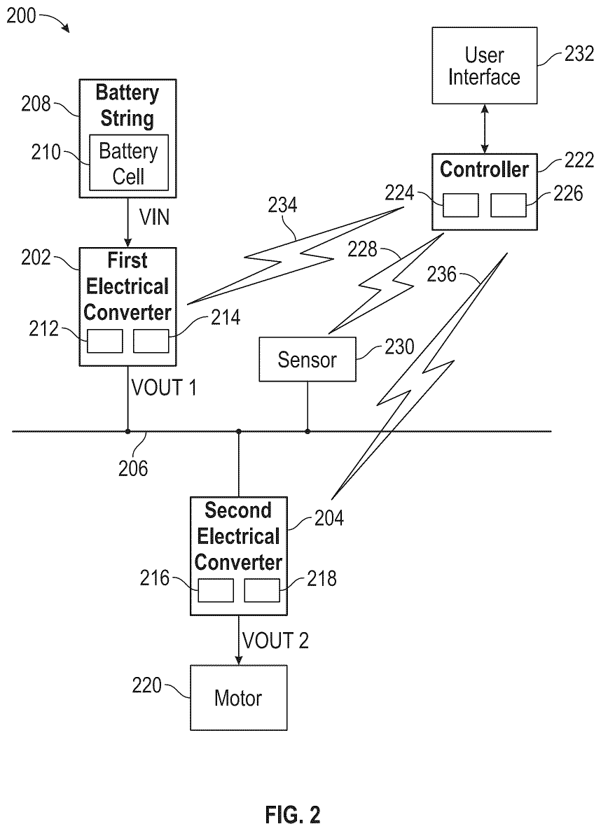

FIG. 2 is a simplified block diagram of an example of an electrical system that may implement various techniques of this disclosure. The electrical system 200 of FIG. 2 is an example of the electrical system 112 of the mobile machine 100 of FIG. 1.

The electrical system 200 includes a first electrical converter 202 and a second electrical converter 204. Electrical converters include DC/DC converters, AC/DC converters, and DC/AC converters. Each of the first electrical converter 202, e.g., a DC/DC converter, and the second electrical converter 204, e.g., an AC/DC converter, are coupled with an electrical bus 206.

A voltage source, such as including at least one battery string 208, is electrical coupled with the electrical bus 206. In FIG. 2, the battery string 208 is electrical coupled with the electrical bus 206 via the first electrical converter 202. The battery string 208 includes at least one battery cell 210.

The first electrical converter 202 includes switching elements 212, e.g., transistors. The operation of the switching elements 212 is controlled by signals, e.g., pulse-width modulation (PWM) signals, from a controller 214. The controller 214 is configured to turn the switching elements 212 ON and OFF at a switching frequency to convert an input voltage VIN to an output voltage VOUT1. The output voltage VOUT1 is applied to the electrical bus 206.

Similarly, the second electrical converter 204 includes switching elements 216, e.g., transistors. The operation of the switching elements 216 is controlled by signals from the controller 218. The controller 218 is configured to turn the switching elements 216 ON and OFF at a switching frequency to convert the voltage VOUT1 at the electrical bus 206 to another output voltage VOUT2.

An electrical device is configured to receive the output voltage VOUT2. In the example shown in FIG. 2, the second electrical converter 204 is a DC/AC converter and the electrical device coupled to receive the output voltage VOUT2 is an electrical motor 220.

Although two electrical converters are shown in FIG. 2 for simplicity, in complex systems, many components are all on a common DC electrical bus 206. AC ground fault detection systems may identify a fault on the bus, but finding the problematic component in a complex system may still require significant troubleshooting time. This disclosure describes techniques to identify which component has the ground fault based on a frequency content.

The electrical system 200 includes a controller 222 including a processor 224 and a memory 226. The controller 222 is in electrical communication, via a communication link 228, with a sensor 230 electrically coupled with the electrical bus 206 configured for sensing an electrical parameter of the electrical bus 206. In some examples, the communication link 228 is a wired connection and, in other examples, the communication link 228 is a wireless connection. The sensor 230 includes one or both of a voltage sensor and a current sensor to measure one or more electrical parameters(s), e.g., voltage and/or current, of the electrical bus 206.

Using the techniques of this disclosure, the first electrical converter 202, and, in particular, its switching elements 212, is configured for operating at a first switching frequency, and the second electrical converter 204, and, in particular, its switching elements 216, is configured for operating at a second switching frequency, where the first switching frequency is different from the second switching frequency. The controller 222 is configured to receive the sensed electrical parameter, e.g., current and/or voltage, via the communication link 228.

The controller 222 is configured to detect ground faults by detecting, using the sensed electrical parameter from the sensor 230, the first switching frequency (of the first electrical converter 202) and/or the second switching frequency (of the second electrical converter 204). By way of a non-limiting example for purposes of explanation only, the controller 214 of the first electrical converter 202 may be operating the switching elements 212 at 3000 Hertz (Hz) and the controller 218 of the second electrical converter 204 may be operating the switching elements 216 at 3100 Hz.

The controller 222 is further configured for identifying, based on the detected switching frequency (or switching frequencies), one or both of the first electrical converter 202 and the second electrical converter 204 as the source of a ground fault. The electrical system 200 may include a user interface 232 in electrical communication with the controller 222. Once the controller 222 has identified one or both of the first electrical converter 202 and the second electrical converter 204 as the source of the ground fault, the controller 222 may generate and output data to the user interface 232, such as including a display and/or a speaker, to communicate information to a user regarding the identified component.

In some examples, the controller 222 is in electrical communication with the first electrical converter 202 and, in particular, its controller 214, via a communication link 234, e.g., wired or wireless. Similarly, the controller 222 is in electrical communication with the second electrical converter 204 and, in particular, its controller 218, via a communication link 236, e.g., wired or wireless.

The controller 222 may be configured to operate in a normal mode and a service mode. For example, the controller 222 may operate in the normal mode during ordinary use of the mobile machine 100 of FIG. 1 and in the service mode when the mobile machine is taken out of service for maintenance or diagnostic purposes.

In the normal mode, the controller 222 generates and transmits a signal to the first electrical converter 202 to operate its switching elements 212 at a first switching frequency. In addition, in the normal mode, the controller 222 may transmit the same signal or a similar signal to the second electrical converter 204 to operate its switching elements 216 at the first switching frequency.

In the service mode, the controller 222 generates and transmits a signal to the first electrical converter 202 to operate its switching elements 212 at the first switching frequency. In addition, in the service mode, the controller 222 may transmit the same signal or a similar signal to the second electrical converter 204 to operate its switching elements 216 at the second switching frequency, where the first switching frequency and the second switching frequency are different switching frequencies. By operating the two (or more) electrical converters at different switching frequencies, the controller 222 may identify which converter has an AC ground fault.

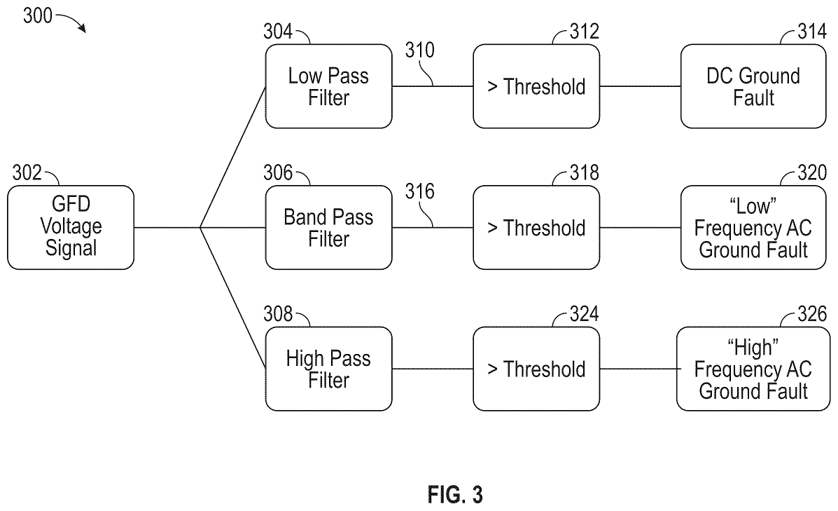

FIG. 3 is a flow diagram 300 of an example of AC ground fault detection using the techniques of this disclosure. The sensor 230 of FIG. 2 senses an electrical parameter 302, e.g., voltage signal, of the electrical bus 206. Using the communication link 228, the sensor 230 transmits data representing the electrical parameter 302 to the controller 222 of FIG. 2.

The controller 222 includes or is configured to implement one or more filters, e.g., digital filters, such as a low pass filter 304, band pass filter 306, and/or a high pass filter 308. The low pass filter 304 is configured to attenuate or block frequencies above the lower of the first switching frequency and the second switching frequency. If an amplitude of the frequency content 310 of the electrical parameter 302 is greater than a threshold 312, the controller 222 identifies the electrical parameter 302 as containing information indicative of a DC ground fault 314. The controller 222 of FIG. 2 may transmit data to the user interface 232 to alert a user, e.g., to a display and/or a speaker of the user interface 232, of the identity of the electrical component that it has determined to be the source of the fault.

The band pass filter 306 is configured to attenuate or block frequencies below the first switching frequency and above the first switching frequency. If an amplitude of the frequency content 316 of the electrical parameter 302 is greater than a threshold 318, the controller 222 identifies the electrical parameter 302 as containing information indicative of a “low” frequency AC ground fault 320, such as associated with a first electrical converter. The controller 222 of FIG. 2 may transmit data to the user interface 232 to alert a user, e.g., to a display and/or a speaker of the user interface 232, representing the identity of the electrical converter that it has determined to be the source of the fault. For example, if the AC ground fault has frequency content of 3000 Hz and the controller 214 was operating the switching elements 212 of the first electrical converter 202 at 3000 Hz, the controller 222 determines that the first electrical converter 202 has the AC ground fault.

In some examples, the band pass filter 306 includes a second (or more) band pass filters. For example, the band pass filter 306 may include a second filter configured to attenuate or block frequencies below the second switching frequency and above the second switching frequency, which may be compared against another threshold so that the controller 222. The controller 222 identifies the electrical parameter 302 as containing information indicative of a “low” frequency AC ground fault 320. The controller 222 of FIG. 2 may transmit data to the user interface 232 to alert a user, e.g., to a display and/or a speaker of the user interface 232, representing the identity of the electrical component that it has determined to be the source of the fault. For example, if the AC ground fault has frequency content of 3100 Hz and the controller 218 was operating the switching elements 216 of the second electrical converter 204 at 3100 Hz, the controller 222 determines that the second electrical converter 204 has the AC ground fault.

The high pass filter 308 is configured to attenuate or block frequencies below the second switching frequency. If an amplitude of the frequency content 310 of the electrical parameter 302 is greater than a threshold 324, the controller 222 identifies the electrical parameter 302 as containing information indicative of a “high” frequency AC ground fault 326, such as associated with another electrical converter. The controller 222 of FIG. 2 may transmit data to the user interface 232 to alert a user, e.g., to a display and/or a speaker of the user interface 232, representing the identity of the electrical converter that it has determined to be the source of the fault.

As mentioned above, the high-pass filter 308 is designed to block frequencies below the second switching frequency. In the configuration shown in FIG. 3, any converter operating at the highest switching frequency does not require a band-pass filter. Instead, the converter may utilize the high-pass filter. It should be noted that, in some examples, multiple band-pass filters may be used, depending on the number of switching frequencies involved. However, the described system includes two switching frequencies and, as such, the high-pass filter is used to detect an AC ground fault in the second converter, which is based on the assumption that it has the higher switching frequency.

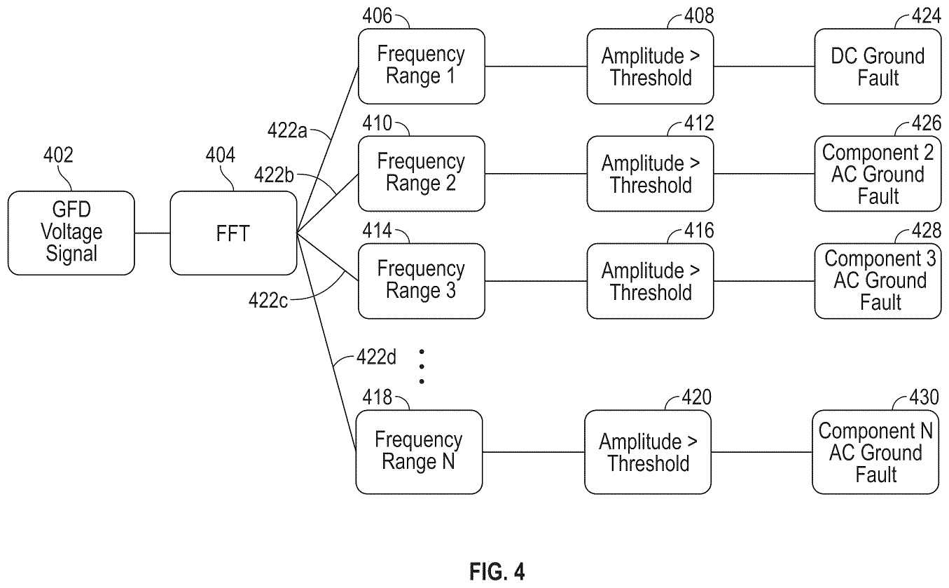

FIG. 4 is a flow diagram 400 of another example of AC ground fault detection using the techniques of this disclosure. The sensor 230 of FIG. 2 senses an electrical parameter 402, e.g., voltage signal, of the electrical bus 206. Using the communication link 228, the sensor 230 transmits data representing the electrical parameter 402 to the controller 222 of FIG. 2.

The controller 222 is configured to analyze a frequency content of the sensed electrical parameter to determine whether the first switching frequency and/or the second switching frequency is present, such as by performing a Fourier transform 404, e.g., a fast Fourier transform (FFT), on the sensed electrical parameter and generate output signal 422a through output signal 422d, which may be the same signal.

Each electrical converter coupled with the electrical bus 206 may be operating at a different switching frequency so that each electrical converter may be identified by the frequency content of the sensed electrical parameter. A first electrical converter 202 may be operated at the first switching frequency.

The controller 222 may implement frequency ranges with corresponding thresholds. For example, it may implement a first frequency range 406 having a corresponding threshold 408, a second frequency range 410 having a corresponding threshold 412, a third frequency range 414 having a corresponding threshold 416, and so forth to an Nth frequency range 418 having a corresponding threshold 420.

If an amplitude of the frequency content of the electrical parameter 402 is within the first frequency range 406 and greater than a corresponding threshold 408, the controller 222 identifies the electrical parameter 402 as containing information indicative of a DC ground fault 424, such as associated with a first electrical converter. The controller 222 of FIG. 2 may generate and transmit data to the user interface 232 to alert a user, e.g., to a display and/or a speaker of the user interface 232 representing the identified electrical converter.

If an amplitude of the frequency content of the electrical parameter 402 is within the second frequency range 410 and greater than a corresponding threshold 412, the controller 222 identifies the electrical parameter 402 as containing information indicative of an AC ground fault associated with a second electrical converter 426. The controller 222 of FIG. 2 may generate and transmit data to the user interface 232 to alert a user, e.g., to a display and/or a speaker of the user interface 232 representing the identified electrical converter.

If an amplitude of the frequency content of the electrical parameter 402 is within the third frequency range 414 and greater than a corresponding threshold 416, the controller 222 identifies the electrical parameter 402 as containing information indicative of an AC ground fault associated with a third electrical converter 428. The controller 222 of FIG. 2 may generate and transmit data to the user interface 232 to alert a user, e.g., to a display and/or a speaker of the user interface 232 representing the identified electrical converter.

This process may be repeated for N electrical components. If an amplitude of the frequency content of the electrical parameter 402 is within the Nth frequency range 418 and greater than a corresponding threshold 420, the controller 222 identifies the electrical parameter 402 as containing information indicative of an AC ground fault associated with an Nth electrical converter 430. The controller 222 of FIG. 2 may generate and transmit data to the user interface 232 to alert a user, e.g., to a display and/or a speaker of the user interface 232 representing the identified electrical converter.

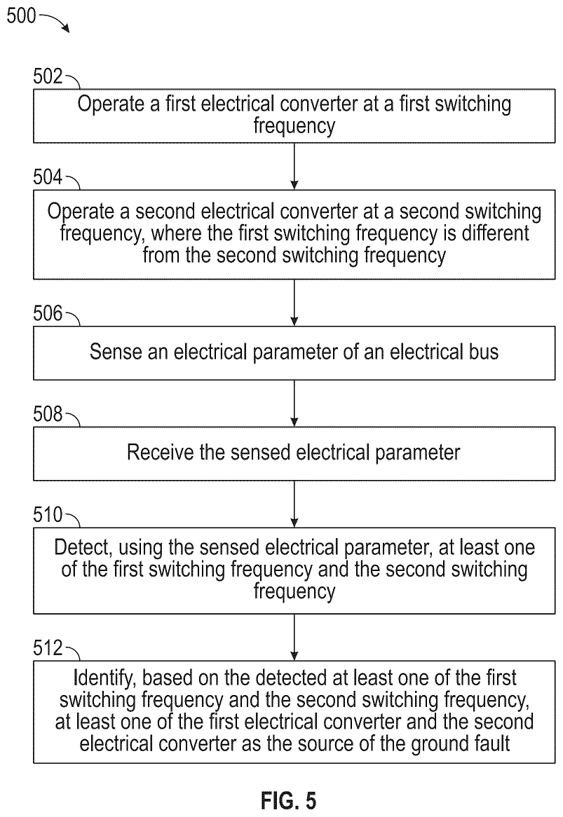

FIG. 5 is a flow diagram of an example of a method 500 for detecting a source of a ground fault in a mobile machine. At block 502, the method 500 includes operating a first electrical converter at a first switching frequency. For example, the controller 214 of the first electrical converter 202 of FIG. 1 operates the switching elements 212 at a first switching frequency, e.g., 3000 Hz.

At block 504, the method 500 includes operating a second electrical converter at a second switching frequency, where the first switching frequency is different from the second switching frequency. For example, the controller 218 of the second electrical converter 204 of FIG. 1 operates the switching elements 216 at a second switching frequency, e.g., 3100 Hz.

At block 506, the method 500 includes sensing an electrical parameter of an electrical bus. For example, the sensor 230 of FIG. 1 senses a voltage on the electrical bus 206.

At block 508, the method 500 includes receiving the sensed electrical parameter. For example, the controller 222 of FIG. 1 receives, via the communication link 228, data representing the sensed electrical parameter, e.g., voltage, from the sensor 230.

At block 510, the method 500 includes detecting, using the sensed electrical parameter, at least one of the first switching frequency and the second switching frequency. For example, the controller 222 includes or is configured to implement one or more filters, such as shown and described with respect to FIG. 3. In another example, the controller 222 is configured to analyze a frequency content of the sensed electrical parameter to determine whether the first switching frequency and/or the second switching frequency is present, such as by performing a Fourier transform 404, such as shown and described with respect to FIG. 4.

At block 512, the method 500 includes identifying, based on the detected at least one of the first switching frequency and the second switching frequency, at least one of the first electrical converter and the second electrical converter as the source of the ground fault. For example, if an amplitude of the frequency content of the electrical parameter is greater than a threshold, the controller 222 identifies the electrical parameter as containing information indicative of an AC ground fault. The controller 222 then determines which electrical converter has the AC ground fault based on the information indicative of the AC ground fault. For example, if the AC ground fault has frequency content of 3100 Hz and the controller 218 was operating the switching elements 216 of the second electrical converter 204 at 3100 Hz, the controller 222 determines that the second electrical converter has the AC ground fault.

In some examples, the controller 222 generates and outputs data to the user interface 232, such as including a display and/or a speaker, to communicate information to a user regarding which electrical converter the controller 222 identified had the ground fault.

In some examples, the method 500 includes filtering to block frequencies below the first switching frequency and the second switching frequency.

In some examples, the method 500 includes filtering to block frequencies below the first switching frequency and above the first switching frequency, and filtering to block frequencies below the second switching frequency and above the second switching frequency.

In some examples, the method 500 includes analyzing a frequency content of the sensed electrical parameter to determine a presence of one or more of the first switching frequency and the second switching frequency, such as by performing a Fourier transform on the sensed electrical parameter.

In some examples, the method 500 includes, in a service mode: operating the first electrical converter at the first switching frequency, and operating the second electrical converter at the second switching frequency.

In some examples, the method 500 includes, in a normal mode: operating the first electrical converter at the first switching frequency; and operating the second electrical converter at the first switching frequency.

### INDUSTRIAL APPLICABILITY

The disclosed techniques for ground fault detection and isolation are particularly beneficial in the context of mobile machines used in industries such as mining, construction, and heavy hauling. These machines, which often operate in harsh and demanding environments, rely on robust power converter systems to manage electrical drives and power distribution. The disclosed techniques enable these mobile machines to detect ground faults swiftly and accurately, ensuring the safety of operators and the protection of expensive equipment from potential damage due to electrical failures. By minimizing the risk of unscheduled downtime and extending the operational life of the machinery, the disclosed techniques contribute to enhanced productivity and reduced operational costs in these sectors.

The automotive industry, especially with the increasing prevalence of electric vehicles (EVs), also stands to gain from the disclosed ground fault detection system. EVs depend on power converters for battery management and electric motor control. The disclosed techniques enhance vehicle safety and reliability, protecting against electrical hazards and preventing damage to components, which in turn extends the service life of the vehicle and reduces the likelihood of expensive recalls.

Additionally, the industrial manufacturing sector, which uses a wide range of motor drives and automated machinery, benefits from the improved ground fault detection capabilities. The integration of the disclosed techniques into the power electronics of these systems helps to avoid unscheduled downtime and equipment failure, leading to better productivity and lower maintenance costs.

In summary, the industrial applicability of the disclosed techniques is extensive and impactful, offering significant safety, reliability, and efficiency improvements across a wide range of sectors that depend on sophisticated power converter systems.

### Various Notes

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A mobile machine configured for detecting a source of a ground fault, the mobile machine comprising:
a battery string including at least one battery cell;
an electrical bus coupled with the battery string;
a first electrical converter and a second electrical converter, each of the first electrical converter and the second electrical converter coupled with the electrical bus, the first electrical converter configured for operating at a first switching frequency and the second electrical converter configured for operating at a second switching frequency, wherein the first switching frequency is different from the second switching frequency;
a sensor coupled with the electrical bus and configured for sensing a electrical parameter of the electrical bus; and
a controller configured to receive the sensed electrical parameter, the controller configured to detect ground faults by:
detecting, using the sensed electrical parameter, at least one of the first switching frequency and the second switching frequency; and
identifying, based on the detected at least one of the first switching frequency and the second switching frequency, at least one of the first electrical converter and the second electrical converter as the source of the ground fault.

2. The mobile machine of claim 1, comprising:
a filter configured to block frequencies below the first switching frequency and the second switching frequency.

3. The mobile machine of claim 1, comprising:
a first filter configured to block frequencies below the first switching frequency and above the first switching frequency; and
a second filter configured to block frequencies below the second switching frequency and above the second switching frequency.

4. The mobile machine of claim 1, wherein detecting, from the sensed electrical parameter, at least one of the first switching frequency and the second switching frequency includes:
analyzing a frequency content of the sensed electrical parameter to determine a presence of one or more of the first switching frequency and the second switching frequency.

5. The mobile machine of claim 4, wherein analyzing the frequency content of the sensed electrical parameter includes:
performing a Fourier transform on the sensed electrical parameter.

6. The mobile machine of claim 1, wherein the first electrical converter includes at least one of a DC/DC converter and an AC/DC converter.

7. The mobile machine of claim 1, wherein the controller is a first controller, wherein the mobile machine is configured for operating in a normal mode and a service mode, wherein in the service mode, a second controller is configured for:
operating the first electrical converter at the first switching frequency; and
operating the second electrical converter at the second switching frequency.

8. The mobile machine of claim 7, wherein in the normal mode, the mobile machine is configured for:
operating the first electrical converter at the first switching frequency; and
operating the second electrical converter at the first switching frequency.

9. A method for detecting a source of a ground fault in a mobile machine, the method comprising:
operating a first electrical converter at a first switching frequency;
operating a second electrical converter at a second switching frequency, wherein the first switching frequency is different from the second switching frequency;
sensing an electrical parameter of an electrical bus;
receiving the sensed electrical parameter;
detecting, using the sensed electrical parameter, at least one of the first switching frequency and the second switching frequency; and
identifying, based on the detected at least one of the first switching frequency and the second switching frequency, at least one of the first electrical converter and the second electrical converter as the source of the ground fault.

10. The method of claim 9, comprising:
filtering to block frequencies below the first switching frequency and the second switching frequency.

11. The method of claim 9, comprising:
filtering to block frequencies below the first switching frequency and above the first switching frequency; and
filtering to block frequencies below the second switching frequency and above the second switching frequency.

12. The method of claim 9, wherein detecting, from the sensed electrical parameter, at least one of the first switching frequency and the second switching frequency includes:
analyzing a frequency content of the sensed electrical parameter to determine a presence of one or more of the first switching frequency and the second switching frequency.

13. The method of claim 12, wherein analyzing the frequency content of the sensed electrical parameter includes:
performing a Fourier transform on the sensed electrical parameter.

14. The method of claim 9, comprising:
in a service mode:
operating the first electrical converter at the first switching frequency; and
operating the second electrical converter at the second switching frequency.

15. The method of claim 14, comprising:
in a normal mode:
operating the first electrical converter at the first switching frequency; and
operating the second electrical converter at the first switching frequency.

16. A mobile machine configured for detecting a source of a ground fault, the mobile machine comprising:
a battery string including at least one battery cell;
an electrical bus coupled with the battery string;
a first electrical converter and a second electrical converter, each of the first electrical converter and the second electrical converter coupled with the electrical bus, the first electrical converter configured for operating at a first switching frequency and the second electrical converter configured for operating at a second switching frequency, wherein the first switching frequency is different from the second switching frequency;
a voltage sensor coupled with the electrical bus and configured for sensing a voltage of the electrical bus;
a controller configured to receive the voltage, the controller configured to detect ground faults by:
detecting, using the voltage, at least one of the first switching frequency and the second switching frequency; and
identifying, based on the detected at least one of the first switching frequency and the second switching frequency, at least one of the first electrical converter and the second electrical converter as the source of the ground fault; and
a user interface configured to receive data from the controller representing the identified at least one of the first electrical converter and the second electrical converter as the source of the ground fault.

17. The mobile machine configured of claim 16, comprising:
a first filter configured to block frequencies below the first switching frequency and above the first switching frequency.

18. The mobile machine configured of claim 16, wherein detecting, from the voltage, at least one of the first switching frequency and the second switching frequency includes:
analyzing a frequency content of the voltage to determine a presence of one or more of the first switching frequency and the second switching frequency.

19. The mobile machine configured of claim 18, wherein analyzing the frequency content of the voltage includes:
performing a Fourier transform on the sensed electrical parameter.

20. The mobile machine configured of claim 16, wherein the controller is a first controller, wherein the mobile machine is configured for operating in a normal mode and a service mode, wherein in the service mode, a second controller is configured for:
operating the first electrical converter at the first switching frequency; and
operating the second electrical converter at the second switching frequency.
